(19) United States
(12) Patent Application Publication
(10) Pub. No.: US 2005/0263892 A1
(43) Pub. Date: Dec. 1, 2005

(54) Method of forming copper interconnection in semiconductor device and semiconductor device using the same

(75) Inventor: In Kyu Chun, Yeoju-gun (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/143,025

(22) Filed: May 31, 2005

(30) Foreign Application Priority Data
Jun. 1, 2004 (KR) 10-2004-0039521

(51) Int. Cl. H01L 23/52; H01L 21/4763

(52) U.S. Cl. 257/751; 438/639; 438/627; 438/687; 257/762

(57) ABSTRACT

A method of forming a copper interconnection in a semiconductor device is suitable for solving a problem generated from an insulating interlayer of fluorine-doped silicate glass being in direct contact with a large surface area of a barrier metal film or being exposed to air over a correspondingly large surface area when forming a copper interconnection in an insulating interlayer pattern formed on a semiconductor substrate. The method includes steps of forming an insulating interlayer on a semiconductor substrate; patterning the insulating interlayer to form a conductor well; forming a protective layer on an inner sidewall of the conductor well; and sequentially depositing a barrier metal film and a Cu seed on the protective layer to complete a filling of the conductor well.

This application claims the benefit of Korean Patent Application No. 10-2004-0039521, filed on Jun. 1, 2004, which is hereby incorporated by reference as if fully set forth herein.

### BACKGROUND OF THE INVENTION

1. Field of the Invention

The present invention relates to a method of forming a copper (Cu) interconnection in a semiconductor device and a semiconductor device using the same. Although the present invention is suitable for a wide scope of applications, it is particularly suitable for solving a problem generated from an insulating interlayer of fluorine-doped silicate glass being in direct contact with a large surface area of a barrier metal film or being exposed to air over a correspondingly large surface area when forming a copper interconnection in an insulating interlayer pattern deposited on a semiconductor substrate.

2. Discussion of the Related Art

Semiconductor devices, including chip-based diodes and transistors, are fabricated by growing a single-crystalline ingot from high-purity silicon extracted from silicon oxide (e.g., sand), cutting the ingot into a disc shape to form a semiconductor substrate providing for a plurality of chips, patterning a layer formed on the semiconductor substrate and implanting impurity ions to form electrically active (doped) areas accordingly, performing at least one metal wiring step, and selecting and separating from the thus-processed semiconductor substrate those chips exhibiting acceptable electrical characteristics. The metal wiring step forms a predetermined set of conductive patterns for connecting the active areas according to the specific semiconductor device being fabricated. Although tungsten and aluminum have been traditionally used as the conductive material for forming the metal wiring layer to be patterned, increasing attention has focused on the use of copper, i.e., a Cu metal layer, which, although more difficult to etch directly, has a lower specific resistance than that of tungsten or aluminum and exhibits excellent robustness.

Meanwhile, a damascene process is applicable to the formation of copper interconnections without etching the Cu metal layer and is part of a next generation wiring process for fabrication of highly integrated devices with faster operation. The damascene process is carried out by pre-patterning a lower layer and forming a metal wire (conductor) according to the pattern, that is, without etching the wiring layer directly, and is generally categorized as a single damascene process forming a via preferentially and then forming the conductor or as a dual damascene process forming the via and conductor simultaneously.

Referring to FIG. 1, illustrating a dual damascene process according to a related art, a lower electrode 102 is formed in a semiconductor substrate 101, for example, by doping the semiconductor substrate to create active areas in accordance with a predetermined pattern. The lower electrode may, for example, be the source or drain of a transistor, to be interconnected by the conductive material of a patterned metal wiring layer. An etch-stop layer 103, a lower insulating interlayer 110, and an upper insulating interlayer 111 are sequentially stacked on the semiconductor substrate 101 to be disposed over at least the lower electrode 102. The material of the lower and upper insulating interlayers 110 and 111 is generally fluorine-doped silicate glass (FSG) having an increased concentration of fluorine to produce a lower dielectric constant.

Subsequently, a portion of each of the insulating interlayers 110 and 111 is removed selectively, i.e., according to predetermined patterns, to thereby form a conductor well 115 for receiving the conductive material, namely, a barrier metal film 120 and a Cu seed 130, in a via formed in the lower insulating interlayer and a trench formed in the upper insulating interlayer. The trench portion of the conductor well 115 receives the conductive material, to form the bulk of any interconnection, while the via portion of the conductor well enables an electrical connection of the conductive material in the trench to the semiconductor substrate 101. The barrier metal film 120 and the Cu seed 130 are sequentially deposited in the conductor well 115, which is fully formed before deposition, to form a copper wire of a dual damascene process.

The increased concentration of fluorine in the lower and upper insulating interlayers 110 and 111, however, degrades adhesion with respect to the barrier metal film 120 and results in peeling after deposition of the barrier metal film, which degrades the electromigration and stress migration characteristics of the semiconductor device and thus produces a less robust semiconductor device. As an ensuing consequence, such fluorine concentrations should be limited. Moreover, as the lower and upper insulating interlayers 110 and 111 are exposed to air inside the conductor well 115, the FSG therein reacts to the water vapor in the air to produce fluorinated silicon dioxide (SiOF) as part of a silicon dioxide (SiO₂) layer, which inherently forms on the entire inner surface of the conductor well due to the exposure and is an impediment to subsequent processes for copper wire formation. In particular, the SiO₂ layer resists the deposition of the barrier metal film 120, causing the occurrence of wiring errors, which induces malfunctions in the fabricated device and lowers its reliability.

### SUMMARY OF THE INVENTION

Accordingly, the present invention is directed to a method of forming a copper interconnection in a semiconductor device and a semiconductor device using the same that substantially obviates one or more problems due to limitations and disadvantages of the related art.

An object of the present invention is to provide a method of forming a copper interconnection in a semiconductor device, in which a separate protective layer forming step is included to reduce surface contact between an insulating interlayer and a barrier metal film and to reduce the insulating interlayer's exposure to air when forming a Cu wire by a dual damascene process, so that electromigration and stress migration characteristics can be maintained to enhance the robustness and reliability of the device.

Another object of the present invention is to provide a method of forming a copper interconnection in a semiconductor device, in which the concentration of fluorine in the FSG material of an insulating interlayer can be raised as necessary to lower the dielectric constant as desired.

Another object of the present invention is to provide a method of forming a copper interconnection in a semiconductor device, which inhibits a reaction between the fluorine in an exposed portion of an insulating interlayer and the water vapor in the air surrounding the exposed portion.

Another object of the present invention is to provide a method of forming a copper interconnection in a semiconductor device, which inhibits the formation of an undesirable SiO₂ layer on inner sidewalls of a conductor well for forming the copper interconnection.

Another object of the present invention is to provide a method of forming a copper interconnection in a semiconductor device, which minimizes the aggravation of such problems in a fabricated semiconductor device as peeling, poor adhesion, degraded electromigration and stress migration characteristics, and the occurrence of wiring errors.

Another object of the present invention is to provide a semiconductor device having a copper interconnection formed by any one of the above methods.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages in accordance with the purpose of the invention, as embodied and broadly described herein, there is provided a method of forming a copper interconnection in a semiconductor device, comprising forming an insulating interlayer on a semiconductor substrate; patterning the insulating interlayer to form a conductor well; forming a protective layer on an inner sidewall of the conductor well; and sequentially depositing a barrier metal film and a Cu seed on the protective layer to complete a filling of the conductor well.

In a preferred embodiment of the present invention, the insulating interlayer is formed of fluorine-doped silicate glass and the protective layer is formed of undoped silicate glass.

According to another aspect of the present invention, there is provided a semiconductor device having a copper interconnection, comprising a semiconductor substrate; an insulating interlayer formed on the semiconductor substrate and patterned to form a conductor well; a protective layer formed on an inner sidewall of the wire connecting portion; and a barrier metal film and a Cu seed sequentially deposited on the protective layer to complete a filling of the conductor well.

It is to be understood that both the foregoing general description and the following detailed description of the present invention-are exemplary and explanatory and are intended to provide further explanation of the invention as claimed.

BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional diagram of a Cu wire formed by a dual damascene process according to a related art;

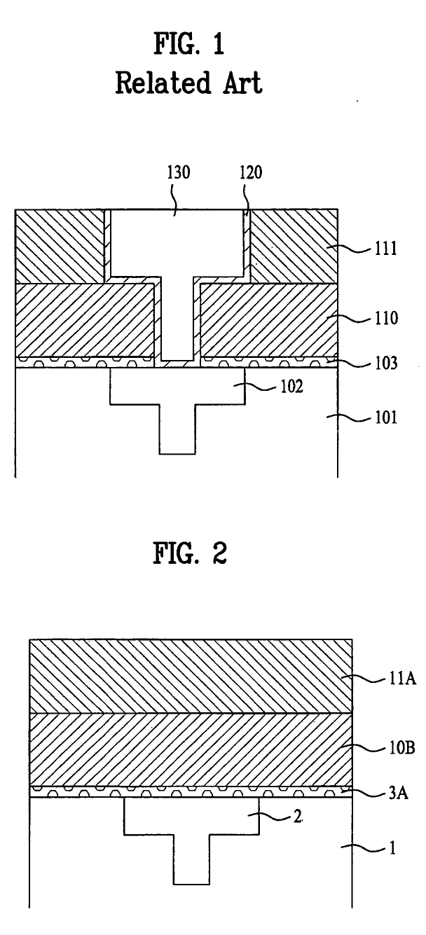

FIG. 2 is a cross-sectional diagram of a dual-structure insulating interlayer for performing a dual damascene process in a method of forming a copper interconnection in a semiconductor device according to the present invention;

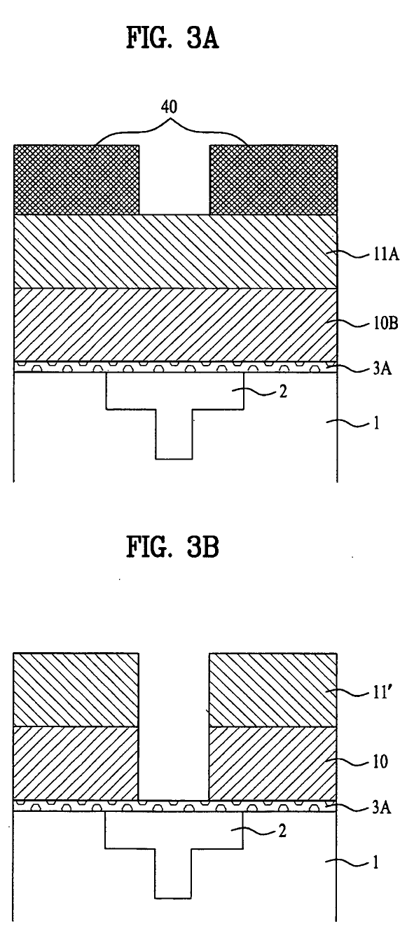

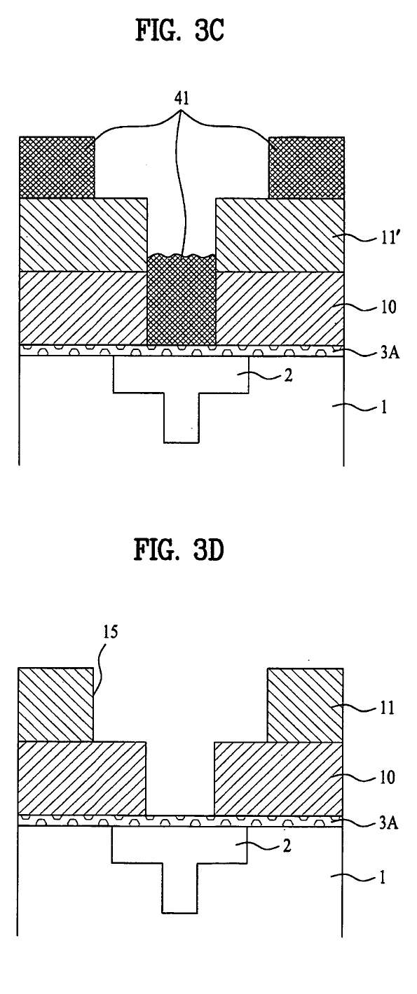

FIGS. 3A-3D are cross-sectional diagrams illustrating a complex conductor well formation for performing a dual damascene process in a method of forming a copper interconnection in a semiconductor device according to the present invention;

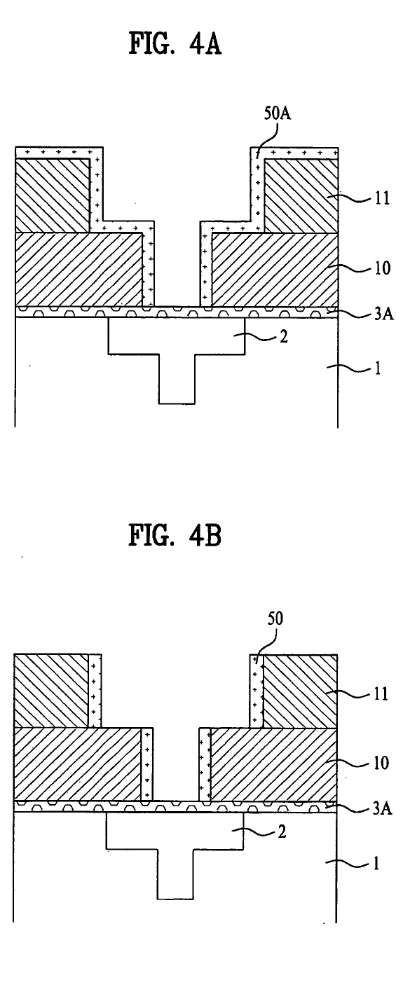

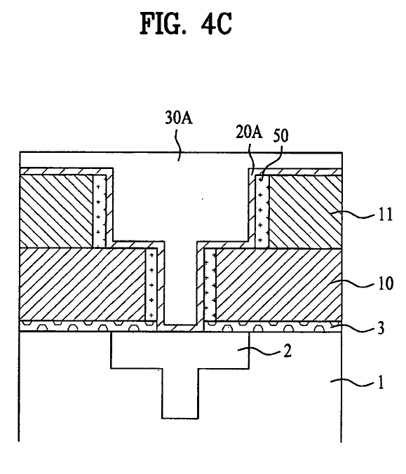

FIGS. 4A-4C are cross-sectional diagrams illustrating a protective layer formation in a method of forming a copper interconnection in a semiconductor device according to the present invention; and

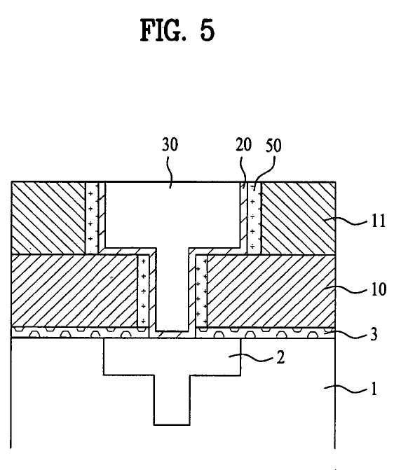

FIG. 5 is a cross-sectional diagram of a semiconductor device having a copper interconnection formed by the method of the present invention.

### DETAILED DESCRIPTION OF THE INVENTION

Reference will now be made in detail to the preferred embodiments of the present invention, examples of which are illustrated in the accompanying drawings. Wherever possible, like reference numbers will be used throughout the drawings to refer to the same or similar parts.

Referring to FIG. 2, specific areas of a semiconductor substrate 1 are doped to form a lower electrode 2 communicating with a surface of the semiconductor substrate, and an etch-stop layer 3A, a lower insulating interlayer 10A, and an upper insulating interlayer 11A are sequentially stacked on the semiconductor substrate to be disposed over at least the lower electrode. The lower and upper insulating interlayers 10A and 11A, which are preferably formed of fluorine-doped silicate glass (FSG), have disparate etch selectivities and are separately deposited to construct a dual structure, i.e., upper and lower layers, for distinguishing predetermined areas for forming a trench and a via using a dual damascene process. The etch-stop layer 3A, generally formed of silicon nitride (SiN) or silicon carbide (SiC) by a plasma process at a temperature below approximately 400° C., prevents an inadvertent etching of the lower electrode 2 at the time of etching either of the lower and upper insulating interlayers 10A and 11A.

Referring to FIGS. 3A-3D, a complex conductor well 15, i.e., trench plus via, for a predetermined inter-wire isolation and electrical connection is formed through a selective removal of the insulating interlayer material using the respective etch selectivities of the lower and upper insulating interlayers 10A and 11A. As shown in FIG. 3A, after coating the upper insulating interlayer 11A with photoresist, a mask having a predetermined pattern is overlaid on the photoresist, which is then exposed to ultraviolet light, to produce a first photoresist pattern 40 by removing the exposed portion of the photoresist. As shown in FIG. 3B, the first photoresist pattern 40, which corresponds to the via of the complex conductor well 15, is used to simultaneously etch both of the lower and upper insulating interlayers 10A and 11A, to form a lower insulating interlayer pattern 10 having the same pattern as an intermediate upper insulating interlayer pattern 11′. A separate photo-etching step is employed to form the trench of the complex conductor well by coating the resulting structure of FIG. 3B with another layer of photoresist, which undergoes a similar photoresist exposure and selective removal process to form a second photoresist pattern 41. Here, after the selective removal of photoresist as shown in FIG. 3C, a portion of the photoresist remains in the via portion of the complex conductor well at a level substantially below the surface of the intermediate upper insulating interlayer pattern 11′. As shown in FIG. 3D, the previously exposed portion of the intermediate upper insulating interlayer pattern 11′ is etched to complete the complex conductor well 15, including a trench formed in an upper insulating interlayer pattern 11 and a via formed in the lower insulating interlayer pattern 10. Here, the via portion of the complex conductor well 15 communicates with the trench portion thereof and effectively forms a terminus of the trench portion for establishing an electrical connection to the lower electrode 2, and a copper interconnection formed by the method of the present invention comprises the conductive material filling the both the via and the trench.

In a general dual damascene process, the sequential deposition of a barrier metal film and Cu seed for forming a wire immediately follows the formation of the trench and via, in which case the fluorine-doped FSG insulating interlayer with its high fluorine concentration is exposed to air before such deposition and reacts with the water vapor in the air to form an undesirable SiO₂ layer, leading to such problems as peeling, poor adhesion, degraded electromigration and stress migration characteristics, and the occurrence of wiring errors. To overcome these problems, the present invention employs a protective layer, preferably of undoped silicate glass (USG), for capping the FSG insulating interlayers. Notably, undoped silicate glass contains no dopant that may trigger an undesired chemical reaction as described above.

Referring to FIG. 4A, a layer 50A of undoped silicate glass is deposited onto the structure of FIG. 3D to cover the inner surfaces of the complex conductor well 15, particularly extending into the trench formed in the upper insulating interlayer pattern 11 and the via formed in the lower insulating interlayer pattern 10. The thickness of the deposition of the undoped silicate glass of the USG layer 50A determines the thickness of the protective layer to be formed. As shown in FIG. 4B, the USG layer 50A is etched by reactive ion etching to remove an upper surface portion of the USG layer to form a USG protective layer 50 in which the inner sidewalls of the complex conductor well 15 retain a protective layer of undoped silicate glass capping the exposed side surfaces of the FSG material of the lower and upper insulating interlayer patterns 10 and 11, after which the via portion of the complex conductor well for providing contact with the lower electrode 2 is completed by dry etching the etch-stop layer 3A, to perforate the etch-stop layer, using as a mask the USG protective layer and the insulating interlayer patterns. Thereafter, as shown in FIG. 4C, a barrier metal 20A and a Cu seed layer 30A are sequentially deposited on the USG protective layer 50 to establish an electrical contact with the lower electrode 2 within the via of the complex conductor well 15.

Finally, as shown in FIG. 5, a barrier metal film 20 and a Cu seed 30 are etched back by chemical mechanical polishing to complete the formation of a wire having a copper interconnection of a semiconductor device according to the present invention. Due to the inclusion of the USG protective layer 50 on the inner sidewalls of the via and trench, the horizontal dimensions of the complex conductor well 15 formed according to the present invention are controlled to secure a compensated space allowing for a sufficient volume of the copper interconnection wire formed by the barrier metal film 20 and Cu seed 30. That is, the horizontal dimensions of the complex conductor well 15 formed according to the present invention is slightly greater than in the related art method.

Referring to FIG. 5, a semiconductor device having a copper interconnection formed by the method of the present invention includes the lower electrode 2 formed by doping a predetermined area of the semiconductor substrate 1 below the copper interconnection to be formed; the perforated etch-stop layer 3 formed on the semiconductor substrate under the insulating interlayer formation; an insulating interlayer formed on the semiconductor substrate and patterned to form the complex conductor well 15, the insulating interlayer being constituted as a dual structure including the lower and upper insulating interlayer patterns 10 and 11; the USG protective layer 50 formed on an inner sidewall of the complex conductor well 15; and the barrier metal film 20 and the Cu seed 30 sequentially deposited on the USG layer to complete a filling of the complex conductor well. Thus, the complex conductor well 15 provides for an electrical contact by the wire to the lower electrode 2 through the via of the complex conductor well, and the via communicates with the trench portion thereof, which forms a majority of the complex conductor well for receiving the sequentially deposited barrier metal film 20 and Cu seed 30.

Accordingly, the method of the present invention, in which the USG protective layer 50 is disposed between the barrier metal film 20 and the FSG material of the lower and upper insulating interlayer patterns 10 and 11, solves the problems stemming from the fluorine component of the insulating interlayer material that is deposited (stacked) in forming a copper interconnection by a dual damascene process. That is, by an FSG insulating interlayer with a USG protective layer, the present invention prevents the problems caused by a direct contact between FSG material and a large surface area of a barrier metal film or by the FSG material being exposed to air over a correspondingly large surface area. The core principle of the present invention of using a separate protective layer (cap) for inhibiting the undesired chemical reaction of the related art is easily applicable to various other fields by those skilled in the art, including a single damascene process and other processes for semiconductor device fabrication that include instances of Cu wiring. It should be appreciated that the adverse effects of the related art method, such as the undesirable production of fluorinated silicon dioxide and the ensuing formation of a silicon dioxide layer on the etched surfaces of the insulating interlayers, are appreciably destructive when acting on vertical surfaces of a conductor well; also, the effects of the present invention overcome the above adverse effects as applied to a limited portion of the conductor well's contacting surfaces, e.g., the horizontal surfaces of a complex conductor well.

By adopting the method of forming a copper interconnection in a semiconductor device according to the present invention, FSG-to-barrier metal film adhesion properties are minimized and rendered inconsequential. Thus, the concentration of fluorine in the FSG material of an insulating interlayer can be raised as necessary to lower the dielectric constant as desired, a high degree of device robustness can be maintained by preventing a degradation of electromigration and stress migration characteristics, and device reliability is improved by inhibiting an undesired reaction between fluorine and water vapor that occurs if a large surface area of the FSG insulating interlayer is exposed to air.

It will be apparent to those skilled in the art that various modifications can be made in the present invention without departing from the spirit or scope of the invention. Thus, it is intended that the present invention covers such modifications provided they come within the scope of the appended claims and their equivalents.

1. A method of forming a copper interconnection in a semiconductor device, comprising:
forming an insulating interlayer on a semiconductor substrate;
patterning the insulating interlayer to form a conductor well;
forming a protective layer on an inner sidewall of the conductor well; and
sequentially depositing a barrier metal film and a Cu seed on the protective layer to complete a filling of the conductor well.

2. The method of claim 1, wherein the insulating interlayer is formed of fluorine-doped silicate glass.

3. The method of claim 2, wherein the protective layer is formed of undoped silicate glass.

4. The method of claim 1, further comprising:
etching the protective layer using reactive ion etching.

5. The method of claim 4, wherein said etching removes an upper surface portion of the protective layer.

6. The method of claim 5, wherein the conductor well has horizontal dimensions compensating for a thickness of the formed protective layer to secure a sufficient volume of the sequentially deposited barrier metal film and Cu seed.

7. The method of claim 1, wherein the insulating interlayer is formed as a dual structure including lower and upper insulating interlayers for performing a dual damascene process.

8. The method of claim 1, further comprising:
forming a wire by etching back the sequentially deposited barrier metal film and Cu seed using chemical mechanical polishing.

9. The method of claim 1, said protective layer forming comprising:
depositing a layer of material onto the patterned insulating interlayer to cover inner surfaces of the conductor well; and
etching the deposited layer using reactive ion etching to remove an upper surface portion of the deposited layer.

10. The method of claim 9, wherein the material for forming the insulating interlayer is fluorine-doped silicate glass and the material for forming the protective layer is undoped silicate glass.

11. The method of claim 1, further comprising:
doping a predetermined area of the semiconductor substrate to form a lower electrode below the copper interconnection to be formed, the lower electrode being disposed below the insulating interlayer.

12. The method of claim 11, wherein the conductor well provides for an electrical contact by the wire to the lower electrode.

13. The method of claim 12, wherein the electrical contact is achieved through a via of the conductor well.

14. The method of claim 13, wherein the via of the conductor well communicates with a trench portion of the conductor well, the trench portion receiving the sequentially deposited barrier metal film and Cu seed.

15. The method of claim 1, further comprising:
forming an etch-stop layer on the semiconductor substrate under the insulating interlayer.

16. The method of claim 15, further comprising:
dry etching the etch-stop layer, using, using as a mask the protective layer and the patterned insulating interlayer, to perforate the etch-stop layer and thus complete the formation of the conductor well.

17. The method of claim 15, wherein the etch-stop layer is formed of one of silicon nitride (SiN) and silicon carbide (SiC).

18. The method of claim 17, wherein the etch-stop layer is formed by a plasma process at a temperature below approximately 400° C.

19. A semiconductor device having a copper interconnection, comprising:
a semiconductor substrate;
an insulating interlayer formed on said semiconductor substrate and patterned to form a conductor well;
a protective layer formed on an inner sidewall of the wire connecting portion; and
a barrier metal film and a Cu seed sequentially deposited on the protective layer to complete a filling of the conductor well.

20. The semiconductor device of claim 19, wherein the insulating interlayer is formed of fluorine-doped silicate glass.

21. The semiconductor device of claim 20, wherein the protective layer is formed of undoped silicate glass.

22. The semiconductor device of claim 19, further comprising:
a lower electrode formed by doping a predetermined area of said semiconductor substrate below the copper interconnection to be formed, said lower electrode being disposed below the insulating interlayer.

23. The method of claim 22, wherein the conductor well provides for an electrical contact by the wire to said lower electrode, the electrical contact being achieved through a via of the conductor well, the via communicating with a trench portion of the conductor well, the trench portion receiving said sequentially deposited barrier metal film and Cu seed.

24. The semiconductor device of claim 19, further comprising:
an etch-stop layer formed on the semiconductor substrate under the insulating interlayer.

25. The semiconductor device of claim 24, wherein said etch-stop layer is formed of one of silicon nitride (SiN) and silicon carbide (SiC) by a plasma process at a temperature below approximately 400° C.

26. The semiconductor device of claim 19, wherein said insulating interlayer is formed as a dual structure including lower and upper insulating interlayers performing a dual damascene process and wherein the conductor well is a complex conductor well formed of a via portion for an electrical contact of the copper interconnection and a trench portion communicating with the via portion.
